(19) United States
(12) Patent Application Publication
(10) Pub. No.: US 2011/0204497 A1
(43) Pub. Date: Aug. 25, 2011

(54) Semiconductor integrated circuit and method for manufacturing the same

(75) Inventors: Satoru Matsuda, Kanagawa (JP); Tsukasa Yasuda, Kanagawa (JP); Ichiro Matsumoto, Kanagawa (JP)

(73) Assignee: RENESAS ELECTRONICS CORPORATION, Kawasaki (JP)

(21) Appl. No.: 12/929,759

(22) Filed: Feb. 14, 2011

(30) Foreign Application Priority Data
Feb. 24, 2010 (JP) 2010-038893

(51) Int. Cl. H01L 23/495; H01L 21/60

(52) U.S. Cl. 257/669; 438/123; 257/E23.031; 257/E21.506

(57) ABSTRACT

A semiconductor integrated circuit having a semiconductor chip mounted over a tape- or film-like substrate, the semiconductor integrated circuit having a higher strength against bending, as well as a method for manufacturing the semiconductor integrated circuit, are disclosed. The semiconductor integrated circuit comprises a bendable tape-like substrate, the tape-like substrate including external terminals, internal terminals provided for coupling to a rectangular semiconductor chip, and wiring lines for coupling the internal terminals and the external terminals with each other; and a reinforcing member for reinforcing the semiconductor chip over the tape-like substrate in a longitudinal direction of the semiconductor chip, the semiconductor chip and the reinforcing member being sealed with resin.

### CROSS-REFERENCE TO RELATED APPLICATIONS

The disclosure of Japanese Patent Application No. 2010-38893 filed on Feb. 24, 2010 including the specification, drawings and abstract is incorporated herein by reference in its entirety.

### BACKGROUND

1. Field of the Invention

The present invention relates to a semiconductor integrated circuit and a method for manufacturing the same. Particularly, the present invention is concerned with a semiconductor integrated circuit with a semiconductor chip mounted on a tape- or film-like substrate, as well as a method for manufacturing the semiconductor integrated circuit.

2. Description of Related Art

Recently, display devices used in TV and personal computer displays have been becoming larger in screen size and higher in definition and the number of output terminals in ICs for display devices, especially in source drivers, has come to exceed 900.

There also is a great demand for display panels of a so-called narrow frame specification designed to be smaller in the size of a non-display area at the outer periphery of each display panel. In addition, cost competition has increasingly become fierce. Shrinking the chip size of a driver IC is one countermeasure. This is because the manufacturing cost is cut down from the standpoint of both material and man-hour.

On the other hand, also in the packaging mode, a display device IC is required to mount a large number of output terminals in a narrow frame area, so in many cases uses a thin flexible base material and adopts a bendable TAB or COF configuration suppressed in height. Further, with the recent tendency to narrower pitches of output terminals of driver ICs, TCP and COF are now most popular also from the standpoint of connection reliability between a driver IC and a load line of a display device.

Particularly, the driver IC for a display device must be installed within a display device of the recent narrow frame specification. That is, the driver IC for a display device is required to have multiple output terminals, a small area and sufficient thinness.

To meet such conditions there has been proposed a semiconductor integrated circuit wherein an elongated thin chip smaller in short side length and larger in outer periphery length is mounted on a filmy substrate. However, as the chip is made thinner, a geometrical moment of inertia becomes smaller and the chip becomes easier to break and extremely weak against bending in the longitudinal direction after being mounted onto the film, namely, against a force acting on the circuit integration surface of the driver IC. Therefore, it is considered necessary that some improvement be made to the portability as product and the flexural strength in mounting.

COP (Chip on film) type semiconductor integrated circuits with a semiconductor chip mounted on a filmy substrate are described in Japanese Application Publication Nos. 2008-177618, 2001-053108, 2002-158309, Hei09(1997)-246315, and 2002-118127. FIG. 6 is a diagram showing a semiconductor integrated circuit 100 described in Japanese Application Publication No. 2008-177618. As shown in FIG. 6, a semiconductor element 102 is connected to a tape carrier 101 and the gap between the tape carrier 101 and the semiconductor element 102 is sealed with insulating resin 103. Plural salient electrodes 105 are provided on the semiconductor element 102. The tape carrier 101 is for coupling and mounting of the semiconductor element 102 and it includes wiring patterns 107, solder resist 108 and insulating tape 109. The wiring patterns 107 are each different in thickness partially. More specifically, the thickness of only a portion (coupled portion) where the wiring patterns 107 and the semiconductor element 102 are coupled together is smaller than the thickness of the other portion (uncoupled portion). Consequently, in the coupled portion, the pitch of the wiring patterns 107 can be made fine, while in the uncoupled portion it is possible to improve the mechanical strength of the wiring patterns 107 and also possible to improve the strength of the semiconductor integrated circuit 100.

FIG. 7 is a diagram showing a semiconductor integrated circuit 110 described in Japanese Application Publication No. 2001-053108. The semiconductor integrated circuit 110 includes a base film 111, a semiconductor element 113, connections 114 of wiring patterns for connection with the semiconductor element 113, connector portions 115 for external connection of wiring patterns, an adhesive layer 116, a reinforcing member 117 formed by a polyimide-based insulating film, bumps 118 and sealing resin 119. The semiconductor integrated circuit 110 has a wiring pattern-forming surface of an elongated base film 1, and on the side opposite thereto, it has a polyimide-based reinforcing member 117 having a film thickness of 15 to 400 μm. With the reinforcing member 117, the dimensional accuracy of accumulative pitches and strength in the connector portions 115 for external connection of wiring patterns or in the connections of wiring patterns with the semiconductor element 113 are improved in COF or TCP (Tape carrier package) without change in bendability as compared with the conventional COF.

FIG. 8 is a diagram showing a semiconductor integrated circuit 130 described in Japanese Application Publication No. 2002-158309. In a substrate 131, a wiring layer is formed on a surface of a tape base 135, a lead portion 137 and a land portion 138 are provided at both ends respectively of each wiring pattern 136, and apertures 139 are formed in the tape base 135 so that the lands 138 are exposed to a back surface of the tape base. Wiring patterns 136 on a surface of the substrate 131 are covered with solder resist 140 exclusive of the lead portions 137.

On a surface of a chip 132 are provided electrode portions 141 which are connected to a predetermined integrated circuit. The chip 132 is facedown-mounted onto a surface of the substrate 131 and the electrode portions 141, e.g., gold (Au) bumps, are coupled electrically to the lead portions 137 of the substrate 131. Sealing material 133 such as, for example, polyimide resin seals connections between the electrode portions 141 of the chip 132 and the lead portions 137 of the substrate 141. External terminals 134 formed by, for example, tin (Sn) or lead (Pb) or lead-free solder balls are coupled to the land portions 138 electrically through the apertures 139. A reinforcing frame 142 is affixed to the surface of the substrate 131 to prevent deformation of the substrate 131 formed by the tape base 135.

In the above configuration, since the lead portions of the substrate wire-coupled to the chip electrode portions are fixed onto the tape base, it becomes possible to diminish defects caused by lead bending and hence possible to narrow the pad pitch in the semiconductor integrated circuit.

FIG. 9A is a sectional view of a semiconductor integrated circuit 150 described in Japanese Application Publication No. Hei09(1997)-246315 and FIG. 9B is a plan view thereof. In the semiconductor integrated circuit 150, wiring films 153E and 153e as ground lines are extended to a peripheral portion of a film circuit 151, a reinforcing plate 175 having electrical conductivity is used, and the wiring films 153E and 153e as ground lines and the conductive reinforcing plate 175 are coupled together electrically using, for example, conductive paste 176 at the peripheral portion of the film circuit 151. Where required, a heat sink 177 is bonded to a back surface of a semiconductor element 154 and that of the film circuit 151. The semiconductor integrated circuit 150 is fabricated by bonding the reinforcing plate 175 to the film circuit 151, thereafter, locating the semiconductor element 154 at a position enclosed with the reinforcing plate 175, bonding its electrodes to semiconductor element-side terminals of the film circuit 151, and then sealing the reinforcing plate 175, film circuit 151 and semiconductor element 154 with a sealing material 174.

According to this method, the reinforcing plate 175 which surrounds the semiconductor element 154 can be made ground lines and is electrostatically shielded from the other portions. Therefore, the entry of noise from the exterior of the semiconductor device into the semiconductor element 154 is prevented, radiation of noise generated in the interior of the semiconductor element 154 to the exterior is prevented, and crosstalk in the interior of the semiconductor element is prevented by the ground line 153e coupled to the reinforcing plate 175.

FIG. 10 is a diagram showing a semiconductor integrated circuit 180 described in Japanese Application Publication No. 2002-118127. The semiconductor integrated circuit 180 includes a support film 181 for mounting the semiconductor integrated circuit 180, inner leads 182 formed on the support film 181, and a dam portion 183 formed around a chip mounting area and a chip sealing area both provided on the support film 181. According to the technique disclosed in Japanese Application Publication No. 2002-118127, by potting resin from a component side of a semiconductor chip 184, a gap between a bottom of the semiconductor chip 184 and the dam portion 183 formed on the film 181 is sealed with resin 185. Likewise, side faces of the chip 184 and side faces of the dam area are sealed with the resin 185. By using a film having the dam portion, not only it is possible to prevent bending of the inner leads and increase the amount of resin discharged, but also it is possible to prevent insufficient flow of resin onto the chip mounting surface.

### SUMMARY

In the semiconductor integrated circuit described in Japanese Application Publication No. 2008-177618, the thickness of the uncoupled portion is made larger than that of the wiring layer in the coupled portion to improve the mechanical strength of the wiring layer. However, with the structure of merely increasing the thickness of the insulating resin near the coupled portion, particularly if the chip is bent with both long-side ends thereof as fulcrums so that the base member side is concave and the chip surface side is convex, the chip is very likely to break and it is impossible to obtain a sufficient flexural strength.

In the semiconductor integrated circuit described in Japanese Application Publication No. 2001-053108, the strength against bending is reinforced by the reinforcing member 117, but with only the polyimide-based reinforcing member 117 having a thickness of 15 to 400 μm, it is difficult to obtain a sufficient flexural strength.

In the semiconductor integrated circuit described in Japanese Application Publication No. 2002-158309, the gap between the chip 132 and the reinforcing frame 142 is not filled with the sealing material 140 and a sufficient flexural strength against a force acting on the circuit integration surface is not obtained.

In the semiconductor integrated circuit described in Japanese Application Publication No. Hei09(1997)-246315, the gap between the semiconductor element 154 and the reinforcing plate 175 is filled with the sealing material 174, but the reinforcing plate 175 is large in comparison with the semiconductor element 154, not suitable for mounting onto FPC (Flexible Printed Circuits) of long chips such as driver ICs for display devices. Moreover, since the sectional shape of the reinforcing plate 175 is flat, the flexural strength cannot be improved to a satisfactory extent.

In the semiconductor integrated circuit described in Japanese Application Publication No. 2002-118127, a dam area is formed to make up the deficiency in the lapping of resin, with no consideration given therein to improve the strength against bending.

A semiconductor integrated circuit according to an aspect of the present invention comprises a bendable tape-like substrate, the tape-like substrate including external terminals, internal terminals provided for coupling to a rectangular semiconductor chip, and wiring lines for coupling the internal terminals and the external terminals with each other; the rectangular semiconductor chip coupled to the substrate electrically; and a reinforcing member for reinforcing the semiconductor chip over the substrate in a longitudinal direction of the chip, the semiconductor chip and the reinforcing member being sealed with resin.

According to the present invention it is possible to provide a semiconductor integrated circuit having a semiconductor chip mounted over a tape- or film-like substrate, the semiconductor integrated circuit having a higher strength against bending, as well as a method for manufacturing the semiconductor integrated circuit.

### BRIEF DESCRIPTION OF THE DRAWINGS

FIG. 1 is a diagram showing an outline of a semiconductor integrated circuit according to a first embodiment of the present invention;

FIGS. 2A, 2B, and 2C are diagrams showing a section of the semiconductor integrated circuit of the first embodiment;

FIG. 3 is a diagram showing an outline of a semiconductor integrated circuit according to a second embodiment of the present invention;

FIGS. 4A, 4B and 4C are diagrams showing a section of the semiconductor integrated circuit of the second embodiment;

FIG. 5 is a diagram showing a section of a semiconductor integrated circuit according to a third embodiment of the present invention;

FIG. 6 is a diagram showing a conventional semiconductor integrated circuit;

FIG. 7 is a diagram showing another conventional semiconductor integrated circuit;

FIG. 8 is a diagram showing a further conventional semiconductor integrated circuit;

FIGS. 9A and 9B are diagrams showing a still further conventional semiconductor integrated circuit; and

FIG. 10 is a diagram showing a still further conventional semiconductor integrated circuit.

### DETAILED DESCRIPTION OF THE PREFERRED EMBODIMENTS

### First Embodiment

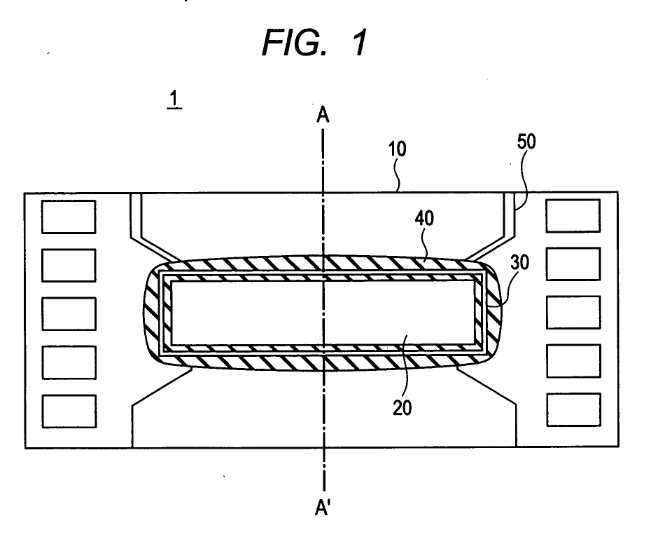

A first embodiment of the present invention will be described with reference to drawings. A semiconductor integrated circuit according to a first embodiment of the present invention has a tape- or film-like package called COP or TCP. FIG. 1 is a diagram showing an outline of a semiconductor integrated circuit 1 of this embodiment. The semiconductor integrated circuit 1 includes a tape-like substrate 10, a semiconductor chip 20, and a reinforcing member 30, the semiconductor chip 20 and the reinforcing member 30 being sealed with resin 40.

The tape-like substrate 10, which is a bendable tape-like substrate, includes external terminals (not shown), internal terminals (not shown) for coupling with the semiconductor chip 20, and wiring lines 50 for coupling the external terminals and the internal terminals with each other.

The semiconductor chip 20 is coupled electrically to the internal terminals of the tape-like substrate 10 through bumps (not shown) of the semiconductor chip 20.

The reinforcing member 30 is in the shape of a frame substantially parallel to the whole circumference of the semiconductor chip 20. A gap between the reinforcing member 30 and the semiconductor chip 20 and a gap between the reinforcing member 30 and the tape-like substrate 10 are sealed with resin 40.

The tape-like substrate 10 used in this embodiment is, for example, a polyimide substrate having a thickness of several hundred micron meters. The semiconductor integrated circuit 1 is disposed on the bendable tape-like substrate 10, so if a force tending to bend the semiconductor integrated circuit 1 is applied to the circuit from the exterior, the chip is apt to break due to the flexibility of the tape-like substrate 10 in comparison with a semiconductor integrated circuit on a substrate having no flexibility. In the semiconductor integrated circuit 1 of this embodiment, by sealing the semiconductor chip 20 coupled to the tape-like substrate 10 and the reinforcing member 30 with resin 40, it is possible to enhance the strength against bending.

The semiconductor integrated circuit 1 of this embodiment will be further described. In the semiconductor integrated circuit 1, the semiconductor chip 20 is disposed on the tape-like substrate 10 and internal terminals of the tape-like substrate 10 and bumps of the semiconductor chips 20 are coupled together electrically and mechanically using, for example, high frequency and ultrasonic wave. Next, the reinforcing member 30 of a frame structure parallel to the whole circumference of the semiconductor chip 20 is disposed, and by utilizing, for example, capillarity, resin 40 is injected between the semiconductor chip 20 and the reinforcing member 30 in a direction substantially perpendicular to the semiconductor chip 20 to seal the gap between the semiconductor chip 20 and the reinforcing member with the resin. Then, the resin 40 is cured by the application of heat to fix the reinforcing member 30 to the tape-like substrate 10.

It is preferable that the gap between the semiconductor chip 20 and the reinforcing member 30 be approximately 0.01 to 0.5 mm. By setting the gap between the semiconductor chip 20 and the reinforcing member 30 at a value of approximately 0.01 to 0.5 mm, there occurs capillarity. Therefore, by injecting resin between the reinforcing member 30 and the semiconductor chip 20, the reinforcing member 30 is self-aligned by capillarity and the gap between the reinforcing member 30 and the tape-like substrate 10 and the gap between the reinforcing member 30 and the semiconductor chip 20 are sealed with resin 40.

As to the gap between the semiconductor chip 20 and the reinforcing member 30, an optimum spacing is determined by the viscosity of the resin 40. Generally, when the semiconductor chip 20 is mounted to the tape-like substrate 10, the gap between the semiconductor chip 20 and the tape-like substrate 10 takes a value of 10 μm or so. It is necessary to use resin 40 having such characteristics as can fill up the said gap and therefore it is preferable that the gap between the semiconductor chip 20 and the reinforcing member 30 take a value of about 0.01 to 0.5 mm. The value of about 0.01 to 0.5 mm may be changed depending on the surface material and machining method in each of the reinforcing member 30, tape-like substrate 10 and semiconductor chip 20 or wettability of the resin 40.

As to the material of the resin 40 it is preferable that in the temperature range of −50° C. to 150° C., the thermal expansion coefficient thereof be relatively close to that of silicon which is the material of the semiconductor chip 20. Further, for sealing the semiconductor chip 20 and the reinforcing member 30 it is preferable that the resin 40 be superior in wettability to both silicon and reinforcing member 30.

By adjusting the wettability of the resin 40, fillet is formed naturally and it is possible to avoid stress concentration. Besides, by adjusting the wettability, the reinforcing member 30, the tape-like substrate 10 and the semiconductor chip 20 can be rendered integral with one another. The wettability can be adjusted by adjusting the surface roughness and surface coating of each of the reinforcing member 30 and the tape-like substrate 10 and by selecting a suitable material of the resin 40.

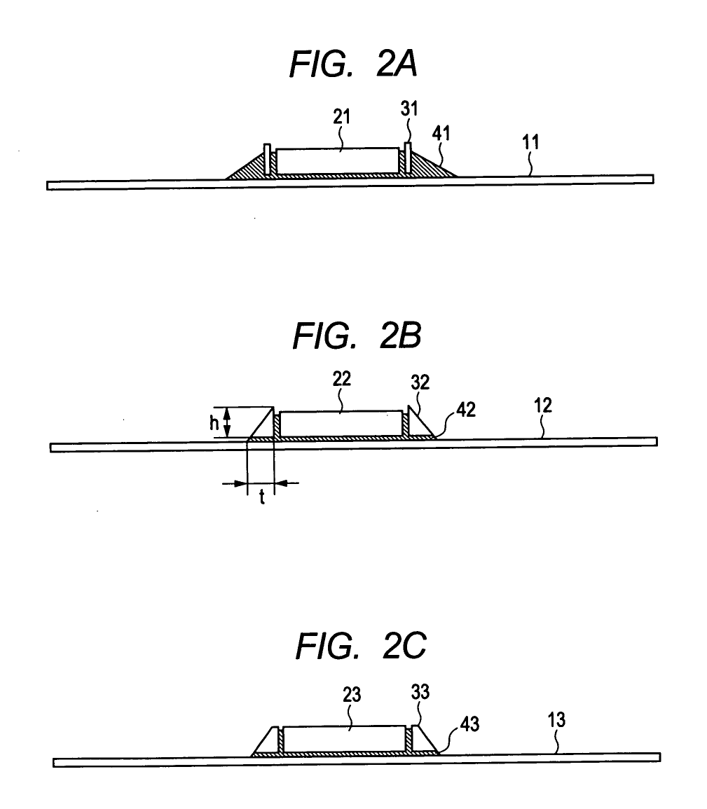

FIGS. 2A to 2C are sectional views of the semiconductor integrated circuit 1 of FIG. 1, taken on line A-A′ in FIG. 1. FIGS. 2A to 2C show first to third examples of the semiconductor integrated circuit 1 of this embodiment, the first example using a tape-like substrate 11, a semiconductor chip 21, a reinforcing member 31 and resin 41, the second example using a tape-like substrate 12, a semiconductor chip 22, a reinforcing member 32 and resin 42, and the third example using a tape-like substrate 13, a semiconductor chip 23, a reinforcing member 33 and resin 43.

FIG. 2A illustrates a semiconductor integrated circuit 1 having a reinforcing member 31 of a rectangular section. FIG. 2B illustrates a semiconductor integrated circuit 1 having a reinforcing member 32 of a generally triangular section which uses a wiring substrate 12 as a base. FIG. 2C illustrates a semiconductor integrated circuit 1 having a reinforcing member 33 of a generally trapezoidal section which uses a tape-like substrate 13 as a base.

In the semiconductor integrated circuits 1, after coupling the semiconductor chips 21 to 23 onto the tape-like substrates 11 to 13 respectively, the reinforcing members 31 to 33 are disposed and sealed with resins 41 to 43 by utilizing capillarity. Therefore, as shown in FIGS. 2A to 2C, the gaps between the semiconductor chips 21 to 23 and the tape-like substrates 11 to 13 and the gaps between the semiconductor chips 21 to 23 and the reinforcing members 31 to 33 are sealed with resins 41 to 43.

A description will now be given about the structures of the reinforcing members 31 to 33. As shown in FIG. 2B, it is here assumed that the height of each of the reinforcing members 31 to 33 is h and a sectional width of each of the reinforcing members 31 to 33 is t. The height h of each of the reinforcing members 31 to 33 may be the same as the height of each of the semiconductor chips, but is preferably larger than the latter. It is advantageous for the reinforcing member 30 to be thick in the direction in which it is bent, in order to increase the section modulus efficiently with use of a small quantity of the frame material. Therefore, since the reinforcing members 31 to 33 come to be integral with the resins 41 to 43, their central portions are difficult to expand outwards when bending the semiconductor integrated circuits 1. Thus, the strength against bending can be enhanced even if the sectional width t of each of the reinforcing members 31 to 33 is small.

As shown in FIG. 2B, the sectional shape of the reinforcing member 30 is high in the vertical direction with respect to the tape-like substrate 10 and the sectional width t of the reinforcing member 30 is smaller than the height h of the reinforcing member 30. In this way the flexural rigidity in the longitudinal direction of the package structure of the semiconductor chip 20 is enhanced more effectively without increasing the chip size.

It is preferable that a sectional height of each of the reinforcing members 31 to 33 be larger than the height of each of the semiconductor chips 21 to 23, but if a protruding height from each of the resins 41 to 43 is too large, a larger package results. Therefore, an appropriate adjustment is desirable.

The reinforcing members 31 to 33 may be electrically conductive insofar as resin can get into the associated gaps to ensure insulation. However, if the semiconductor chips 21 to 23 are different in thermal expansion coefficient from the reinforcing members 31 to 33, there occur thermal stresses, so it is preferable that the reinforcing members 31 to 33 have each a thermal expansion coefficient close to that of silicon and have a high strength.

It is preferable that the reinforcing members 31 to 33 be insulators or have respective surfaces having been treated for insulation. More specifically, it is preferable that the reinforcing members 31 to 33 be each formed of a ceramic material or stainless steel having a treated surface for insulation. By using such materials it is possible to enhance the package strength and heat dissipating property.

The semiconductor integrated circuit 1 of this embodiment can be enhanced its strength against bending by the reinforcing member 30. Besides, by making the reinforcing member 30 and the semiconductor chip 20 integral with each other by the resin 40, the strength against bending can be further enhanced. Consequently, when a bending stress is applied to the semiconductor chip 20 in the longitudinal direction of the chip, it is possible to enhance the flexural strength.

In other words, by virtue of the flexural rigidity of the sectional shape itself of the reinforcing member 30, the flexural rigidity of the resin 40 filled on both inner and outer side faces of the reinforcing member 30, and the flexural rigidity based on bonding between both inner and outer side faces of the reinforcing member 30 and the resin 40, the flexural strength is enhanced effectively.

Thus, according to this embodiment, a semiconductor integrated circuit having a higher strength against bending can be provided by sealing the tape-like substrate 10, the semiconductor chip 20 and the reinforcing member 30 with the resin 40.

### Second Embodiment

A second embodiment of the present invention will be described below with reference to drawings. As to the same components as in the first embodiment, they are identified by the same reference numerals as in the first embodiment, and detailed explanations thereof will be omitted.

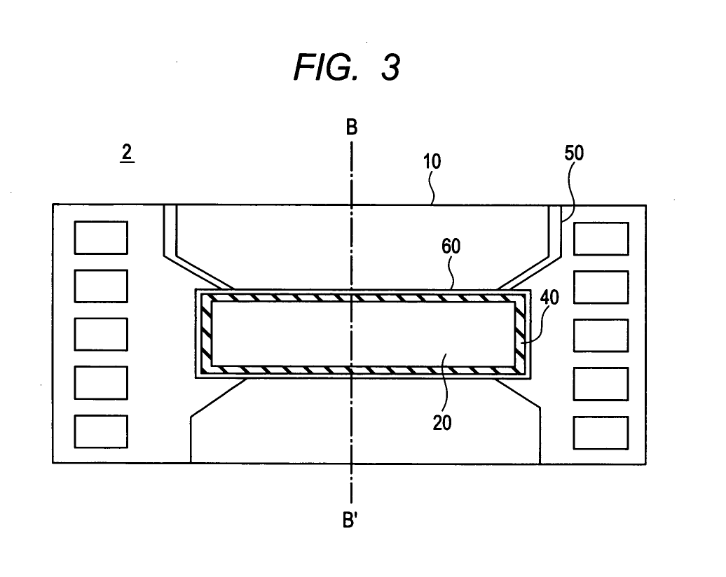

FIG. 3 is a diagram showing an outline of a semiconductor integrated circuit 2 according to the second embodiment. The semiconductor integrated circuit 2 comprises a tape-like substrate 10, a semiconductor chip 20, resin 40, wiring lines 50, and a reinforcing member 60.

The tape-like substrate 10 is a bendable substrate having internal terminals (not shown) for coupling to the semiconductor chip 20 and wiring lines 50 for coupling the internal terminals and external terminals with each other. The semiconductor chip 20, which is a rectangular chip, is coupled electrically to the tape-like substrate 10 and the reinforcing member 60 of a frame structure parallel to the whole circumference of the semiconductor chip 20 is provided. Resin 40 is injected between the semiconductor chip 20 and the reinforcing member 60 in a direction substantially perpendicular to the semiconductor chip 20 to seal between the semiconductor chip 20 and the reinforcing member 60 with the resin 40 and fix the reinforcing member 60 to the tape-like substrate 10.

In fabricating the semiconductor integrated circuit 2, first the reinforcing member 60 is formed on the tape-like substrate 10. The reinforcing member 60 is not specially limited if only a required strength thereof is ensured, provided an insulating material is used at its surface of coupling with the tape-like substrate 10 so as to prevent shorting between wiring lines 50. Like the reinforcing member 30, the reinforcing member 60 is also in the shape of a frame nearly parallel to the whole circumference of the semiconductor chip 20, but it is fixed to the tape-like substrate 10. Therefore, the portion where the semiconductor chip 20 is disposed, including the tape-like substrate 10, is in a bathtub shape. Resin 40 is injected after that, so that the semiconductor chip 20 is enclosed with the reinforcing member 60. Thus, it is possible to prevent spreading of the resin 40.

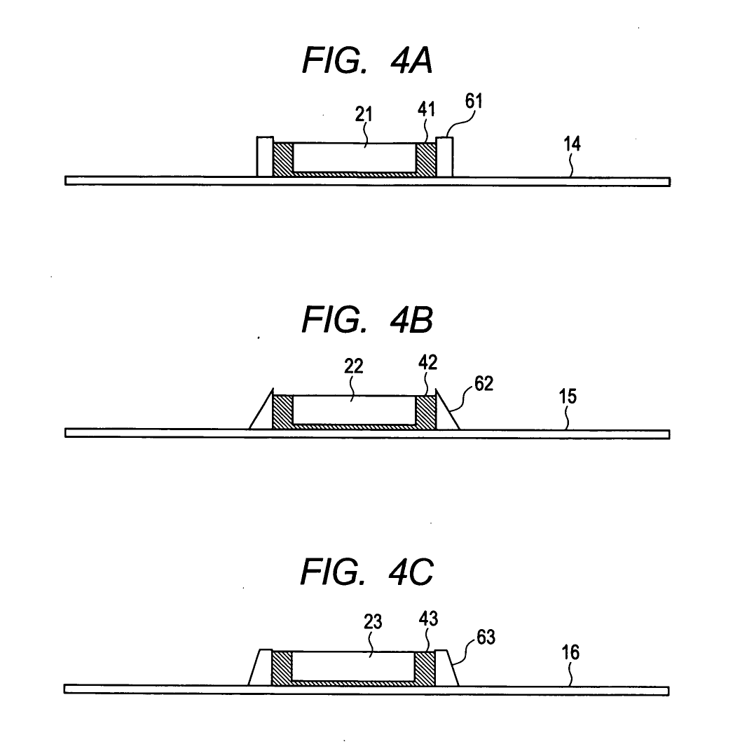

This second embodiment will be further described. FIGS. 4A to 4C are sectional views of the semiconductor integrated circuit 2 of FIGS. 2A to 2C, taken on line B-B′ in FIG. 1. In FIGS. 4A to 4C there are used tape-like substrates 14 to 16, semiconductor chips 21 to 23, reinforcing members 61 to 63, and resins 41 to 44. FIG. 4A illustrates a semiconductor integrated circuit 2 having a reinforcing member 61 of a generally rectangular section. FIG. 4B illustrates a semiconductor integrated circuit 2 having a reinforcing member 62 of a generally triangular section which uses a base of a tape-like substrate 15 as a base. FIG. 4C illustrates a semiconductor integrated circuit 2 having a reinforcing member 63 of a generally trapezoidal section which uses a tape-like substrate 16 as a base. In the case of the semiconductor integrated circuit 1, the reinforcing member 60 is disposed after installing the semiconductor chip 20 and the bonding thereof to the tape-like substrate 10 is conducted with the resin 40, so that the resin 40 is present also under the reinforcing member 60. On the other hand, in the case of the semiconductor integrated circuit 2 of this embodiment, the reinforcing member 60 shown in FIG. 3 is bonded to the tape-like substrate 10 before mounting of the semiconductor chip 20, so that the resin 40 is present only between the reinforcing member 60 and the semiconductor chip 20 and does not lap between the reinforcing member 60 and the tape-like substrate 10.

Accordingly, it is possible to fabricate a semiconductor integrated circuit having an enhanced strength against bending.

### Third Embodiment

A third embodiment of the present invention will be described below with reference to drawings. The same components as in the first and second embodiments are identified by the same reference numerals as in the first and second embodiments, and detailed explanations thereof will be omitted.

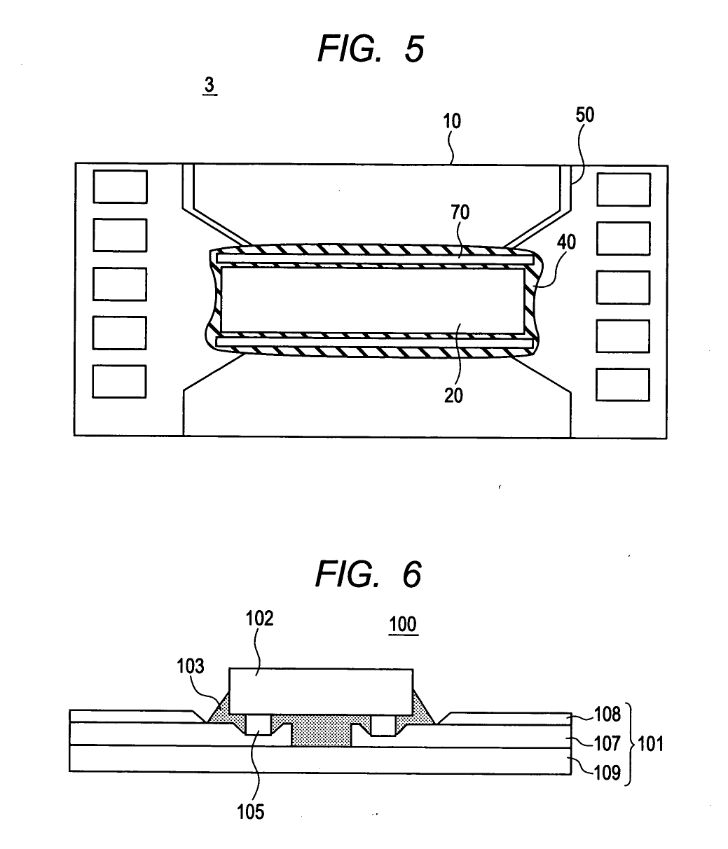

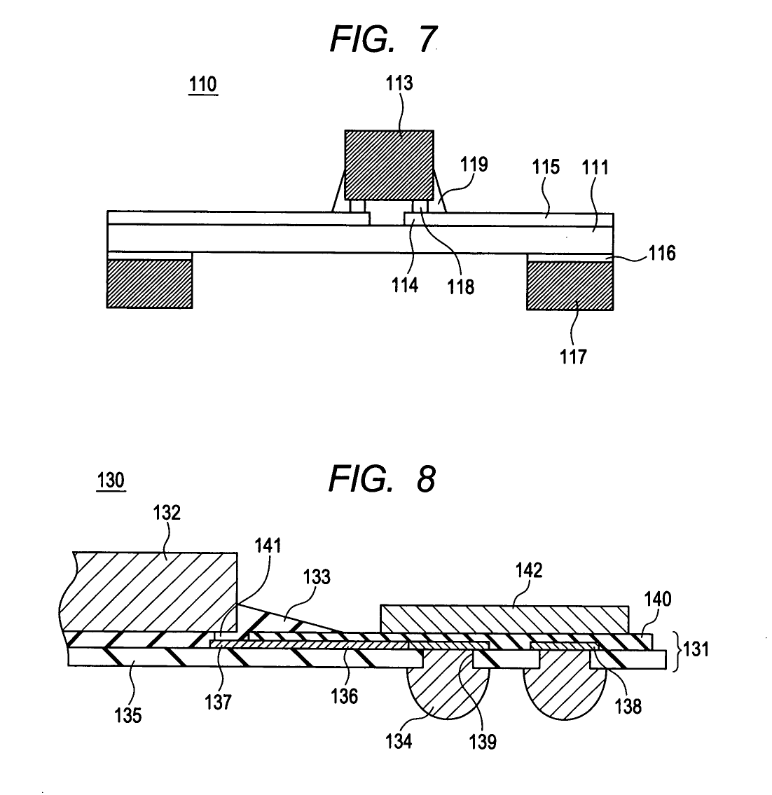

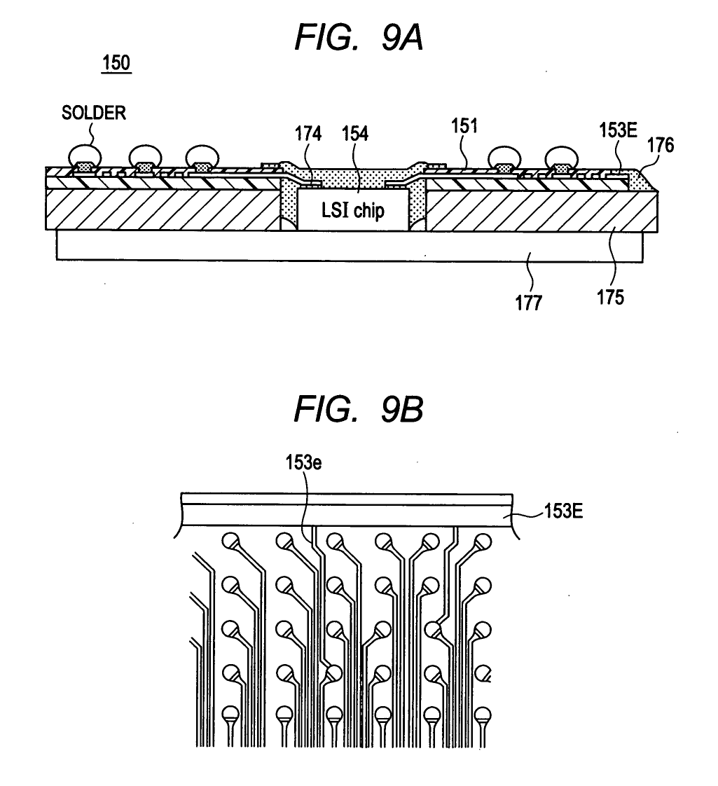

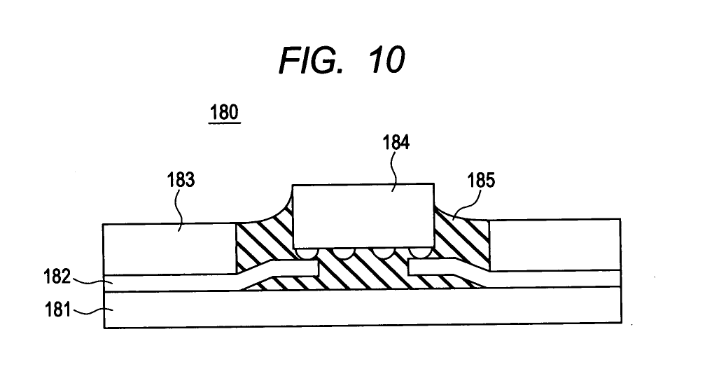

FIG. 5 illustrates a semiconductor integrated circuit 3 of this third embodiment. The semiconductor integrated circuit 3 comprises a tape-like substrate 10, a semiconductor chip 20, wiring lines 50, and reinforcing members 70.

The semiconductor integrated circuit 3 is different from the semiconductor integrated circuit 1 in that it has nearly parallel plate-like reinforcing members 70 in the longitudinal direction of the semiconductor chip 20. The length of each reinforcing member 70 is larger than the length of each long side of the semiconductor chip 20. Each reinforcing member 70 has the same sectional shape and material as those of the reinforcing members used in the other embodiments.

In the case of the semiconductor integrated circuit 3, like the semiconductor integrated circuit 2, resin 40 is injected after fixing the reinforcing members 70 to the tape-like substrate 10. In the other points the semiconductor integrated circuit 3 is the same as the semiconductor integrated circuit 2.

In the semiconductor integrated circuit 3, the semiconductor chip 20 can be reinforced with a smaller quantity of reinforcing members 70.

According to the present invention, a satisfactory flexural strength (flexural rigidity in the longitudinal direction) of COF and TAB package products can be ensured while reducing the chip thickness and without a great increase of weight. Moreover, an increase in the number of packaging steps is suppressed and conventional equipment can be used almost completely. Further, heat capacity increases as an entire package and satisfactory heat dissipation can be expected by selecting a suitable material.

The present invention is not limited to the above embodiments, but changes may be made as necessary within the scope not departing from the gist of the invention.

What is claimed is:

1. A semiconductor integrated circuit comprising:
a bendable tape-like substrate, the tape-like substrate including external terminals, internal terminals provided for coupling to a rectangular semiconductor chip, and wiring lines for coupling the internal terminals and the external terminals with each other;
the rectangular semiconductor chip coupled to the substrate electrically; and
a reinforcing member for reinforcing the semiconductor chip over the substrate in a longitudinal direction of the chip,
wherein the semiconductor chip and the reinforcing member are sealed with resin.

2. The semiconductor integrated circuit according to claim 1, wherein the reinforcing member is in the shape of a frame substantially parallel to the whole circumference of the semiconductor chip.

3. The semiconductor integrated circuit according to claim 1, wherein the reinforcing member is in the shape of a plate substantially parallel to the longitudinal direction of the semiconductor chip, and the length of the reinforcing member in a longitudinal direction thereof is larger than each long side of the semiconductor chip.

4. The semiconductor integrated circuit according to claim 1, wherein a sectional shape of the reinforcing member orthogonal to the longitudinal direction of the reinforcing member is a rectangular shape or a generally triangular or trapezoidal shape using the substrate as a base.

5. The semiconductor integrated circuit according to claim 1, wherein the height of the reinforcing member is larger than that of the semiconductor chip.

6. The semiconductor integrated circuit according to claim 1, wherein the reinforcing member satisfies the following relationship with respect to its height and the length of the base of its section:
height of the reinforcing member>length of the base of the reinforcing member's section.

7. The semiconductor integrated circuit according to claim 1, wherein the reinforcing member is an insulator or a member with a surface having been treated for insulation.

8. The semiconductor integrated circuit according to claim 1, wherein the reinforcing member is formed of a ceramic material or stainless steel having a treated surface for insulation.

9. The semiconductor integrated circuit according to claim 1, wherein a gap of 0.01 to 0.5 mm is present between the reinforcing member and the semiconductor chip.

10. A method for manufacturing a semiconductor integrated circuit, comprising:
coupling a rectangular semiconductor chip electrically to a bendable tape-like substrate, the tape-like substrate including external terminals, internal terminals provided for coupling to the semiconductor chip, and wiring lines for coupling the internal terminals and the external terminals with each other;
providing a reinforcing member of a frame structure parallel to the whole circumference of the semiconductor chip; and
injecting resin between the semiconductor chip and the reinforcing member in a direction substantially perpendicular to the semiconductor chip to seal between the semiconductor chip and the reinforcing member with the resin and fixing the reinforcing member to the substrate.

11. The method according to claim 10, wherein a gap of about 0.01 to 0.5 mm is present between the reinforcing member and the semiconductor chip, the resin is injected between the reinforcing member and the semiconductor chip, the frame structure is self-aligned by capillarity, and gaps among the frame structure, the substrate and the semiconductor chip are sealed with the resin.

12. A method for manufacturing a semiconductor integrated circuit, the semiconductor integrated circuit including a bendable tape-like substrate and a rectangular semiconductor chip coupled to the substrate electrically, the tape-like substrate including external terminals, internal terminals provided for coupling to the rectangular semiconductor chip, and wiring lines for coupling the internal terminals and the external terminals with each other,
the substrate having a reinforcing member parallel to long sides or the whole circumference of the semiconductor chip fixed to the substrate,
the method comprising:
injecting resin between the semiconductor chip and the reinforcing member to seal between the semiconductor chip and the reinforcing member with the resin.
